(19) United States
(12) Patent Application Publication
(10) Pub. No.: US 2014/0114595 A1
(43) Pub. Date: Apr. 24, 2014

(54) Method for Determining a Maximum Available Constant Current of a Battery

(71) Applicants: SAMSUNG SDI CO., LTD., Yongin-si, Gyeonggi-do (KR); ROBERT BOSCH GMBH, Stuttgart (DE)

(72) Inventors: Stefan Wickert, Albershausen (DE); Anne Heubner, Stuttgart (DE)

(73) Assignees: SAMSUNG SDI CO., LTD., Yongin-si, Gyeonggi-do (KR); ROBERT BOSCH GMBH, Stuttgart (DE)

(21) Appl. No.: 14/112,422

(22) PCT Filed: Apr. 4, 2012
(86) PCT No.: PCT/EP2012/056175

§ 371 Date: Dec. 29, 2013

(30) Foreign Application Priority Data
Apr. 21, 2011 (DE) 10 2011 007 884.3

(51) Int. Cl. G01R 31/36

(52) U.S. Cl. CPC G01R 31/3648
USPC 702/63

(57) ABSTRACT

A method for determining a maximum constant current of a battery available over a prediction period is described. The method comprises determining a battery state and determining the solution to a differential equation which describes the temporal development of the battery state over the course of the prediction period with the aid of an equivalent circuit diagram model. A battery management unit is also provided and is configured to carry out the method according to the disclosure. The battery management unit includes a device configured to determine the battery state and a control unit configured to determine the solution to the differential equation. A battery having a battery management unit according to the disclosure and a motor vehicle comprising a battery management unit according to the disclosure or a battery according to the disclosure are also provided.

The present invention relates to a method for determining a maximum constant current of a battery which is available over a prediction time period, a battery management unit which is designed to carry out the method according to the invention, a battery which comprises the battery management unit according to the invention and a motor vehicle which comprises the battery management unit according to the invention or the battery according to the invention.

### PRIOR ART

When batteries are used, in particular in motor vehicles, the question arises as to at what constant current the battery can be discharged or charged at maximum over a determined prediction time period without limits for the operating parameters of the battery, in particular for the cell voltage, being infringed. The prior art discloses two methods of determining such a maximum constant current of a battery which is available over a prediction time period.

In a first method known from the prior art, the maximum available constant current is determined iteratively on the basis of an equivalent circuit diagram model. In this context, in each iteration the battery is simulated over the entire prediction time period while assuming a determined constant current. The iteration starts with a relatively low current value. If the voltage limit of the battery is not reached in the simulation, the current value for the next iteration is increased: if the voltage limit is reached, the iteration is ended. The last current value at which the voltage limit of the battery was not reached in the simulation can then be used as the maximum available constant current. A disadvantage with this method is that the iteration and the simulation require considerable computational expenditure.

In a second method which is known from the prior art, the maximum available constant current is determined on the basis of characteristic diagrams as a function of the temperature and the state of charge. A disadvantage with this method is that the characteristic diagrams require considerable expenditure on storage. Furthermore, it is disadvantageous that owing to the approximations which are inherent in the use of characteristic diagrams which are stored in a discretized fashion it is necessary to provide a safety margin which causes the system to be overdimensioned.

DE 10 2008 004 368 A1 discloses a method for determining a power and/or electric work and/or extractable charge quantity of a battery which is available at a respective point in time, in which method a chronological charge quantity profile is stored as a charge prediction characteristic diagram for each combination of one of a plurality of temperature profiles with one of a plurality of power request profiles or one of a plurality of current request profiles.

### DISCLOSURE OF THE INVENTION

According to the invention, a method is made available for determining a maximum constant current of a battery which is available over a prediction time period. The method comprises determining a battery state, and determining the solution of a differential equation which describes the development of the battery state over time in the course of the prediction time period using an equivalent circuit diagram model.

In this context, the maximum available constant current is preferably defined as that constant current at which at the end of the prediction time period a limit is reached for an operating parameter of the battery. The operating parameter may be, in particular, a cell voltage, and the limit can be an upper limit or lower limit.

In one preferred embodiment, the method also comprises calculating the maximum available constant current by inserting a limit for a cell voltage into the solution of the differential equation.

The equivalent circuit diagram model can be given by a series connection of a first resistance and of a further element, wherein the further element is provided by means of a parallel connection of a second resistance and a capacitance. The determination of the battery state can comprise determining suitable values for the first resistance, the second resistance, the capacitance and the voltage present at the further element.

During the determination of the solution of the differential equation it is preferably presumed that the first resistance, the second resistance and the capacitance are constant over the prediction time period. In addition, during the determination of the solution of the differential equation it is preferably presumed that the current supplied by the battery is constant over the prediction time period.

The invention also makes available a battery management unit which is designed to carry out the method according to the invention. The battery management unit can comprise means for determining the battery state, and a control unit which is designed to determine the solution of the differential equation.

The invention also makes available a battery having a battery management unit according to the invention. In particular, the battery can be a lithium-ion battery.

Finally, the invention makes available a motor vehicle, in particular an electric motor vehicle, comprising a battery management unit according to the invention or a battery according to the invention.

Advantageous developments of the invention are specified in the dependent claims and described in the description.

### DRAWINGS

Exemplary embodiments of the invention are explained in more detail with reference to the drawings and the following description. In said drawings:

FIG. 1 shows an equivalent circuit diagram for use in an exemplary embodiment of the method according to the invention,

FIG. 2 shows a schematic flow chart of an exemplary embodiment of the method according to the invention,

FIG. 3 shows a current diagram comparing the method according to the invention with a characteristic-diagram-based method, and

FIG. 4 shows a voltage diagram comparing the method according to the invention with a characteristic-diagram-based method.

### EMBODIMENTS OF THE INVENTION

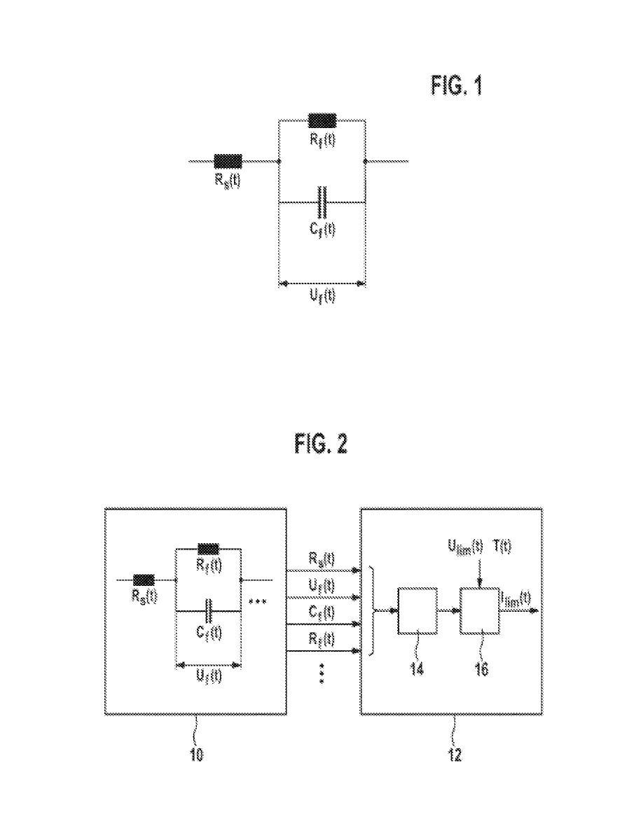

The method according to the invention is based on predicting the chronological development of the battery state using an equivalent circuit diagram model. FIG. 1 shows an example of an equivalent circuit diagram which is suitable for this purpose. In this context, an ohmic resistance Rₛ is connected in series with a further element, wherein the further element is composed of an ohmic resistance R_{f} and a capacitance C_{f} which are connected in parallel (RC element). The resistances Rₛ and R_{f}, the capacitance C_{f} and the voltage U_{f} which is present at the further element are assumed to be time-dependent here. It is also alternatively possible to use an equivalent circuit diagram with any desired number of ohmic resistances and parallel circuits of ohmic resistances and capacitances (RC elements) with any desired parameters.

In order to predict the chronological development of the battery state, a differential equation is set up by means of the equivalent circuit diagram model and then is solved analytically with simplifying assumptions. The cell voltage U_{cell} is given at any point in time by

U_{cell}(t)=U_{OCV}(t)+Uₛ(t)+U_{f}(t)

Here, U_{OCV}(t)=U_{OCV}(SOC(t), θ(t)) denotes the open-circuit voltage which depends on the time via the state of charge SOC(t) and the temperature θ(t), Uₛ(t)=Rₛ(SOC(t), θ(t)·I_{cell}(t) denotes the voltage drop at the resistance Rₛ, wherein the resistance Rₛ depends in turn on the time via the state of charge SOC(t) and the temperature θ(t); I_{cell}(t) denotes the charge current or discharge current at the time t and therefore the current which flows through the resistance Rₛ and the further element connected in series therewith, in the equivalent circuit diagram model; and U_{f}(t) denotes the voltage drop at the further element which is given by the solution of the differential equation valid in the equivalent circuit diagram model:

$${C}_{f} ( S O C ( t ) , θ ( t ) ) \frac{d}{d t} {U}_{f} ( t ) + \frac{{U}_{f} ( t )}{{R}_{f} ( S O C ( t ) , θ ( t ) )} = {I}_{cell} ( t )$$

for t>t₀ and initial value U_{f}⁰=U_{f}(t₀), wherein the resistance R_{f} and the capacitance C_{f} also depend in turn on the time via the state of charge SOC(t) and the temperature θ(t), and t₀ denotes the start of the prediction time period.

Since the purpose of the method is the determination of a maximum constant current, the current I_{cell}(t) is assumed to be constant during the prediction time period. The changes in the parameters Rₛ, R_{f} and C_{f} of the equivalent circuit diagram model which are brought about by changes in the state of charge and the temperature of the battery are small over a typical prediction time period of 2 s or 10 s and can be ignored, with the result that these parameters can be considered to be constant over the prediction time period. Their current values and the current value of the voltage U_{f} at the start of the prediction time period are supplied by the model calculation of the battery state detection (BSD); they form the input values of the prediction process.

The change in the open-circuit voltage owing to the change in the state of charge of the battery is taken into account in a linear approximation, while the change in the open-circuit voltage owing to the change in the temperature is again ignored:

$${U}_{OCV} ( t ) = {U}_{OCV} ( {t}_{0} ) + Δ {U}_{OCV} ( t ) \approx {U}_{OCV} ( {t}_{0} ) + Δ SOC ( t ) \frac{\partial {U}_{OCV}}{\partial SOC} .$$

In this context, the change in the state of charge specified as a percentage of the rated charge (overall capacitance) chCap of the battery is obtained from the current I_{cell} and the time t as

$$Δ SOC ( t ) = 100 \cdot \frac{{I}_{cell} \cdot ( t - {t}_{0 } )}{chCap} .$$

The gradient term

$$\frac{\partial {U}_{OCV}}{\partial S O C} ( S O C ) ,$$

the partial derivative of the open-circuit voltage according to the state of charge, is either calculated once and stored as characteristic diagram or is calculated during operation from the characteristic diagram U_{OCV}(SOC). In both cases, the derivative is calculated here approximately by forming differences, wherein a change in the state of change which results from the current flow I₀=chCap/3600 s=chCap/1 h can be used for example as a measurement for forming differences. SOC(t₀+T) for forming differences is then approximately SOC(t₀)+I₀·T·100/chCap:

$$\frac{\partial {U}_{OCV}}{\partial SOC} ( SOC ) \approx \frac{{U}_{OCV} ( SOC + 100 \cdot \frac{chCap}{1 h} \cdot T / chCap ) - {U}_{OCV} ( SOC )}{100 \cdot \frac{chCap}{1 h} \cdot T / chCap} = \frac{{U}_{OCV} ( SOC + 100 \cdot T / h ) - {U}_{OCV} ( SOC )}{100 \cdot T / h} .$$

With the above assumptions and the time constant τ_{f}=C_{f}R_{f} the simplified differential equation is obtained

$${\dot{U}}_{f} ( t ) = - \frac{1}{{τ}_{f}} {U}_{f} ( t ) + \frac{1}{{C}_{f}} {I}_{cell} ∀ t > {t}_{0} , {U}_{f} ( {t}_{0} ) = {U}_{f}^{0} ,$$

in which only the voltage U_{f}(t) depends on the time. The solution is as follows:

$${U}_{f} ( t ) = {U}_{f}^{0} {e}^{- \frac{t - {t}_{0}}{{τ}_{f}}} + {I}_{cell} {R}_{f} ( 1 - {e}^{- \frac{t - {t}_{0}}{{τ}_{f}}} ) .$$

The entire cell voltage at the point in time t is therefore

$${U}_{cell} ( t ) = {U}_{OCV} ( {t}_{0} ) + 100 \cdot \frac{{I}_{cell} \cdot ( t - {t}_{0} )}{chCap} \cdot \frac{\partial {U}_{OCV}}{\partial SOC} + {U}_{f}^{0} {e}^{- \frac{t - {t}_{0}}{{τ}_{f}}} + {I}_{cell} \cdot {R}_{s} + {I}_{cell} \cdot {R}_{f} \cdot ( 1 - {e}^{- \frac{t - {t}_{0}}{{τ}_{f}}} ) .$$

Resolution according to the constant current I_{cell} then yields

$${I}_{cell} = \frac{{U}_{cell} ( t ) - {U}_{OCV} ( {t}_{0} ) - {U}_{f}^{0} {e}^{- \frac{t - {t}_{0}}{{τ}_{f}}}}{{R}_{s} + {R}_{f} ( 1 - {e}^{- \frac{t - {t}_{0}}{{τ}_{f}}} ) + \frac{100 \cdot ( t - {t}_{0} )}{chCap} \cdot \frac{\partial {U}_{OCV}}{\partial SOC}} .$$

From the condition that at the end of the prediction time period, at the time t=t₀+T, the limit Uₗᵢₘ for the cell voltage U_{cell}(t) is to be complied with it is then possible to calculate the maximum available constant current Iₗᵢₘ by inserting these variables:

$${I}_{lim} = \frac{{U}_{lim} - {U}_{OCV} ( {t}_{0} ) - {U}_{f}^{0} {e}^{- \frac{T}{{τ}_{f}}}}{{R}_{s} + {R}_{f} ( 1 - {e}^{- \frac{T}{{τ}_{f}}} ) + \frac{100 \cdot T}{chCap} \cdot \frac{\partial {U}_{OCV}}{\partial SOC}} .$$

In this context, the approximation for the change in the open-circuit voltage can also be ignored under certain circumstances, which simplifies the formula to

$${I}_{lim} = \frac{{U}_{lim} - {U}_{OCV} ( {t}_{0} ) - {U}_{f}^{0} {e}^{- \frac{T}{{τ}_{f}}}}{{R}_{s} + {R}_{f} ( 1 - {e}^{- \frac{T}{{τ}_{f}}} )} .$$

FIG. 2 shows in a schematic form the profile of the method according to the invention using an exemplary embodiment. During the battery state detection 10, the current values of the parameters Rₛ, R_{f}, C_{f} and U_{f} are determined on the basis of the equivalent circuit diagram model illustrated in FIG. 1. For this purpose, all the available information about the battery can be used, for example the state of health (SOH) of the battery, adapted parameters and/or current values of dynamic state variables. The parameters Rₛ, R_{f}, C_{f} and U_{f} form the input values for the prediction process 12. Firstly, in step 14 the solution of the differential equation is determined on the basis of the parameters Rₛ, R_{f}, C_{f} and U_{f}. For example in this step the values of the parameters Rₛ, R_{f}, C_{f} and U_{f} can be inserted into the general form of the analytic solution in an electronic control unit, wherein the result is a symbolic representation of the dependence of the cell voltage U_{cell}(t) on the time t and the current I_{cell}. This symbolic representation of the voltage profile can also be used for other purposes as well as the determination of a maximum available constant current, for example for determining a voltage which is averaged over the duration T of the prediction time period. In order to determine the maximum available constant current, the duration T=t−t₀ of the prediction time period and a voltage limit Uₗᵢₘ which is to be complied with are then inserted, in step 16, into the solution of the differential equation which is determined in step 14, and as a result the maximum available constant current Iₗᵢₘ is determined. For example in this step the numerical values Uₗᵢₘ for U_{cell}(t) and T for t−t₀ can be inserted into the relationship between U_{cell}(t), I_{cell} and t resolved according to the current I_{cell} in an electronic control unit, in order to determine the maximum constant current Iₗᵢₘ which is available over the prediction time period. All the variables under consideration are, as characterized in the figure, time-dependent; Rₛ, R_{f} and C_{f} are, however, considered to be approximately constant over the prediction time period, and the maximum available constant current Iₗᵢₘ, the voltage limit Uₗᵢₘ to be complied with and the duration T of the prediction time period are constant by definition over the prediction time period, but can assume different values in successive prediction time periods.

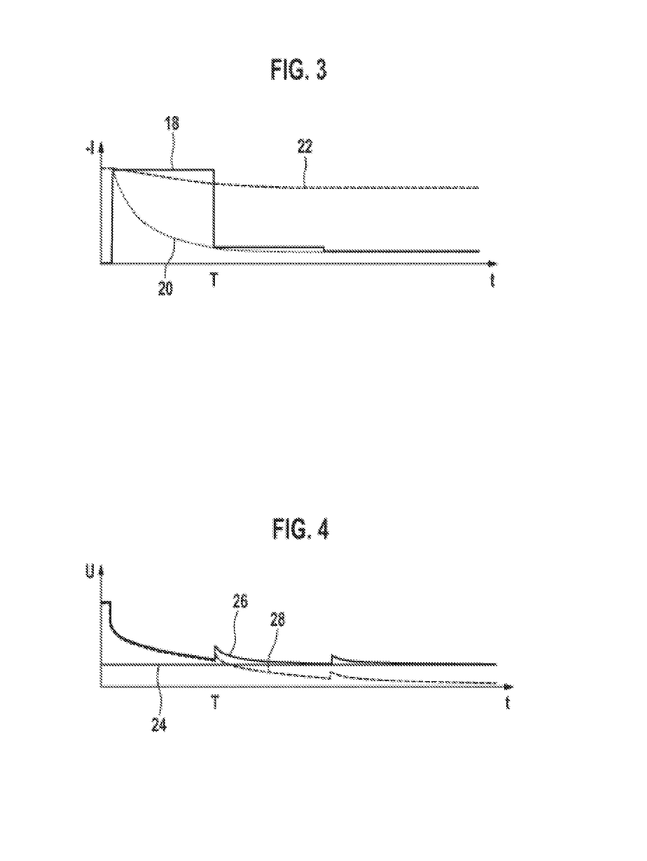

FIG. 3 shows a current diagram comparing the method according to the invention with a characteristic-diagram-based method. The prediction time period comprises in each case a duration T. The graph 18 shows the profile of the current I actually extracted from the battery, as a function of the time t. The graphs 20 and 22 show at each point in time the value which a determination of the maximum available constant current carried out at this point in time for a prediction time period of the length T starting at this point in time would yield. In this context, the graph 20 shows values calculated according to the method according to the invention, and the graph 22 shows values calculated according to a characteristic-diagram-based method. The maximum constant current determined according to the method according to the invention is respectively extracted constantly from the battery over a duration T and then adapted to the current calculation result, as a result of which the step-like profile of the graph 18 is obtained.

FIG. 4 shows a voltage diagram comparing the method according to the invention with a characteristic-diagram-based method. As in FIG. 3, the prediction time period respectively comprises a duration T. 24 denotes the voltage limit which should not be undershot. The graph 26 shows the profile of the battery voltage U as a function of the time t when the method according to the invention is used. The graph 28 shows the profile of the battery voltage U as a function of the time t when the characteristic-diagram-based method is used.

The diagrams illustrate the dynamic adaptation of the current limit compared to the conventional current prediction. By taking into account the exponential term for the voltage at the further element (RC element), the dynamic method ensures that the values remain within the voltage limits and respectively takes into account the cumulated load for the next prediction time period, while the conventional calculation at the end of the first prediction time period for the following time period outputs an excessively high maximum current since it cannot react to the current system state.

It is possible to provide the current limit or the voltage limit with any desired application reserve. Both the time periods and the voltage limits can be applied during the running time. The predicted current values can be used both for the current prediction during the operation of the vehicle and for controlling the charging.

1. A method for determining a maximum constant current of a battery which is available over a prediction time period, comprising:
determining a battery state, and
determining a solution of a differential equation configured to describe a development of the battery state over time in a course of the prediction time period using an equivalent circuit diagram model.

2. The method as claimed in claim 1, wherein:
the maximum available constant current is that constant current at which at an end of the prediction time period a limit is reached for an operating parameter of the battery, and
the operating parameter of the battery is a cell voltage.

3. The method as claimed in claim 2, further comprising:
calculating the maximum available constant current by inserting the limit for the cell voltage into the solution of the differential equation.

4. The method as claimed in claim 1, wherein:
the equivalent circuit diagram model is given by a series connection of a first resistance and of a further element, and
the further element includes a parallel connection of a second resistance and a capacitance.

5. The method as claimed in claim 4, wherein the determination of the battery state includes determining suitable values for the first resistance, the second resistance, the capacitance and a voltage present at the further element.

6. The method as claimed in claim 4, wherein during the determination of the solution of the differential equation it is presumed that the first resistance, the second resistance and the capacitance are constant over the prediction time period.

7. The method as claimed in claim 1, wherein during the determination of the solution of the differential equation it is presumed that a current supplied by the battery is constant over the prediction time period.

8. The method as claimed in claim 1, wherein a battery management unit is configured to carry out the method.

9. The method as claimed in claim 8, wherein the battery management unit includes (i) a device configured to determine the battery state, and (ii) a control unit configured to determine the solution of the differential equation.

10. A battery comprising:
a battery management unit configured to carry out a method for determining a maximum constant current of the battery available over a prediction time period,
wherein the method includes (i) determining a battery state, and (ii) determining a solution of a differential equation configured to describe a development of the battery state over time in a course of the prediction time period using an equivalent circuit diagram model, and
wherein the battery management unit includes (i) a device configured to determine the battery state, and (ii) a control unit configured to determine the solution of the differential equation.

11. The battery as claimed in claim 10, wherein the battery includes a lithium-ion battery.

12. An electric motor vehicle, comprising:
a battery including a battery management unit configured to carry out a method for determining a maximum constant current of the battery available over a prediction time period,
wherein the method includes (i) determining a battery state, and (ii) determining a solution of a differential equation configured to describe a development of the battery state over time in a course of the prediction time period using an equivalent circuit diagram model, and
wherein the battery management unit includes (i) a device configured to determine the battery state, and (ii) a control unit configured to determine the solution of the differential equation.
